(19) United States
(12) Patent Application Publication
(10) Pub. No.: US 2026/0260685 A1
(43) Pub. Date: Sep. 3, 2026

(54) Mixed-Array Dynamic Random-Access Memory (DRAM) Architecture

(71) Applicant: Micron Technology, Inc., Boise, ID (US)

(72) Inventors: Yang Lu, Boise, ID (US); Kang-Yong Kim, Boise, ID (US)

(73) Assignee: Micron Technology, Inc., Boise, ID (US)

(21) Appl. No.: 19/067,434

(22) Filed: Feb. 28, 2025

(51) Int. Cl. G11C 11/4096; G11C 11/4076; G11C 11/4091

(52) U.S. Cl. CPC G11C 11/4096; G11C 11/4076; G11C 11/4091

(57) ABSTRACT

Apparatuses and techniques for implementing mixed-array dynamic random-access memory (DRAM) architecture are described. Processors demand ever faster memories. To meet this demand, DRAM is manufactured with increasing quantities of memory banks. This approach adds area and processing overhead, which translates to increased cost and power usage. This document describes a memory die having a DRAM array with first and second portions that store normal data using memory cells with first and second properties. A first performance property of the first portion is higher than a second performance property of the second portion. Also, a first cost property of the first portion may be higher than a second cost property of the second portion. This mixed-array approach enables some data to be accessed at a higher performance level without resorting to increasing the quantity of memory banks. In some cases, a third portion stores usage-based-disturbance data at a higher performance level.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and nonvolatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses and techniques for implementing mixed-array dynamic random-access memory (DRAM) architecture are described with reference to the following drawings. The same numbers are used throughout the drawings to reference like features and components:

FIG. 1 illustrates example apparatuses that can implement aspects of mixed-array DRAM architecture;

FIG. 2 illustrates example computing systems that can implement aspects of mixed-array DRAM architecture with respect to a memory device;

FIG. 3 illustrates an example memory device in which aspects of mixed-array DRAM architecture can be implemented;

FIG. 4 illustrates an example memory array with multiple bank groups, multiple memory banks, and multiple memory portions in which aspects of mixed-array DRAM architecture may be implemented;

FIG. 5 illustrates example approaches to storing normal data and usage-based-disturbance data within rows of a memory array to support usage-based-disturbance mitigation;

FIG. 6-1 is a schematic diagram illustrating an example DRAM array that includes a first portion and a second portion with each portion having at least one different property;

FIG. 6-2 is a schematic diagram illustrating a memory bank with an example layout of DRAM that includes the first portion and the second portion;

FIG. 6-3 is a schematic diagram illustrating a memory bank with an example layout of DRAM that includes the first portion, the second portion, and a third portion;

FIG. 7-1 is a schematic diagram illustrating a first example allocation of the first and second portions of a memory array across multiple memory banks;

FIG. 7-2 is a schematic diagram illustrating a second example allocation of the first and second portions of a memory array across multiple memory banks;

FIG. 8 depicts example first and second timing diagrams for respectively accessing the first and second portions of a memory array;

FIG. 9-1 illustrates a first example approach to implementing first and second portions of a memory array to produce a mixed-array DRAM architecture having at least one different property across the first and second portions;

FIG. 9-2 illustrates a second example approach to implementing first and second portions of a memory array to produce a mixed-array DRAM architecture having at least one different property across the first and second portions; and

FIG. 10 illustrates example methods for implementing aspects of mixed-array DRAM architecture for a memory device.

### DETAILED DESCRIPTION

### Overview

Computing devices provide various services for users of mobile devices, server devices, and other electronic devices. Some computing devices include a host device, which may include a memory controller, and a memory device for storing information. For certain applications, such as portable electronic devices that operate on battery power and data centers that employ thousands of memory devices, reducing power usage by memory devices can provide appreciable improvements in energy efficiency. These applications may also benefit from increasing memory performance by shortening memory-access latency or reducing periods of memory unavailability. Some implementations that are described herein can provide one or more of these advantages for a memory device or a memory system, including for those employing low-power types of memory.

Double data rate (DDR) synchronous dynamic random-access (SDRAM) memory (DDR SDRAM), which includes low-power DDR (LPDDR) SDRAM, is a volatile memory. Volatile memory loses stored information if the power to the memory is not maintained. The memory cells of DRAM devices are typically fabricated using a transistor and a capacitor, such as by using a transistor and capacitor pair for each memory cell. Information is stored using charge levels that are applied to the capacitors. For instance, a capacitor can be “charged” to a high voltage level or a low voltage level to represent a logical “1” or a logical “0,” respectively. This charge, however, gradually drains from the memory cells, so the data will eventually be lost if the capacitor is not recharged. Consequently, to maintain an appropriate charge that correctly reflects the stored data, the memory cells are refreshed from time-to-time.

This refreshing of memory cells, which can be performed periodically, adds overhead to the use of DRAM. First, additional circuitry at the memory controller and at the DRAM device controls the performance of refresh operations in terms of timing, memory-array location, and so forth. This control circuitry adds area and thus costs to a computing device. Second, the portion of the DRAM that is undergoing the refresh operation is inaccessible during the refresh operation. This adds latency or lowers the bandwidth for accessing data stored in the DRAM device. Nonetheless, DRAM is a popular memory technology because it offers a favorable price per bit of data that is stored relative to the average speed of accessing that data.

DRAM has been used as a relatively low-cost solution for large-density random-access memory (RAM) for many decades. DRAM is relatively cheaper but slower than static random-access memory (SRAM), which does not rely on refreshing. On the other hand, DRAM is more expensive but faster than other storage technologies like flash memory and mechanical hard disks. Since the first generation of DRAM was created, the access timing of DRAM arrays has not been improved. The array timing for a DRAM array can be represented, for instance, by the row cycle time (tRC). Instead of being improved, the array timing has become slower due to difficulties arising from certain characteristics of process scaling. Process scaling involves reducing the size of the capacitors or transistors that form the memory cells to increase memory density and lower memory costs.

Host devices, in contrast with the slowing of DRAM array timing, demand continuous performance increases, such as greater memory bandwidth, year in and year out. To accommodate the demand for increasing performance, each generation of DRAM increases access speed to provide more bandwidth despite the slower array timing. This higher bandwidth is provided by DRAM by offering shorter burst timing. Burst timing is the quantity of cycles between successive column commands (tCCD) to provide repeated chunks of data. A DRAM array can service successive column commands more quickly if the commands target columns in different memory banks of the DRAM array. Accordingly, to achieve higher bus bandwidth, DRAM devices are fabricated with multiple memory banks. In other words, more memory banks can translate into higher memory bandwidth due to the greater available burst length. Unfortunately, increasing a quantity of memory banks results in higher cost due to a die-size penalty from the additional bank logic and bank spacing and results in greater power usage due to more banks remaining open at the same time as well as more control logic being operational.

In contrast with the approach described above that results in manufacturers dividing a memory die into ever more memory banks, this document describes devices and techniques that enable increased memory bandwidth without the overhead associated with adding memory banks. In example implementations, a memory die is fabricated with a mixed-array architecture that produces a DRAM array providing high performance at low cost. The DRAM array includes a first portion of memory cells with a first property and a second portion of memory cells with a second property. The first property can be, for example, a relatively higher performance or a relatively higher cost, including both higher performance and higher cost in accordance with an optional, but permitted herein, inclusive-or interpretation of the disjunctive word “or.” The second property can be, for example, a relatively lower performance or a relatively lower cost as compared to the first property. In some cases, a performance property pertains to speed of access, memory bandwidth, or array timing (e.g., row cycle time).

Being part of a DRAM array, the first portion and the second portion include multiple memory cells with each memory cell including at least one transistor and at least one capacitor. Thus, the first portion and the second portion can be fabricated with the same process technology. Accordingly, fabrication is simplified, and at least some control circuitry can be used across the memory cells of the two portions of the memory array. This contrasts with an alternative approach that adds an SRAM portion to a memory device having a DRAM array. Combining an SRAM array with a DRAM array entails fabricating a memory die with two different process technologies, which adds complexity and cost to the manufacturing process. Further, an SRAM array consumes a significantly higher area per bit than does a DRAM array.

To provide different first and second properties, the structure of the first portion of a DRAM array can be different from the structure of the second portion of the DRAM array. For example, the first portion can include multiple transistors in each memory cell while the second portion includes only one transistor per memory cell. Similarly, the first portion can include multiple capacitors in each memory cell while the second portion includes only one capacitor per memory cell. With multiple transistors, the cost is higher due to the greater area per memory cell, but the speed of access can also be higher. As another example, the first portion can couple memory cells to sense amplifiers with relatively shorter bitlines, and the second portion can couple memory cells to sense amplifiers with relatively longer bitlines. The shorter bitlines enable charge levels to be sensed faster. The shorter bitlines, however, may also result in deploying a greater quantity of sense amplifiers per set of memory cells, which increases the area per bit.

In some implementations, the first portion of memory cells of a DRAM array is designed to store normal data. Normal data can include, for example, user data, data to which the host device can directly read and write—exclusive of control signaling (e.g., not including memory register reads and writes), some combination thereof, and so forth. Similarly, the second portion of memory cells of the DRAM array is also designed to store normal data. In some cases, the first portion does not function as a cache for the second portion. Further, the second portion does not function as a cache for the first portion. Thus, in at least some of such cases, neither portion of memory cells functions as a cache for the other portion. Instead, each memory portion corresponds, for instance, to a separate, non-overlapping range of a joint memory address space. In other words, for at least these cases, neither memory portion is designed to store data for a memory address for which the other memory portion is also designed to store data. Alternatively, for other cases, one memory portion can function as a cache memory for the other portion. For instance, the first portion can function as a cache memory for the second portion such that if data is not located in the first portion of memory cells, the data is stored in the second portion of memory cells.

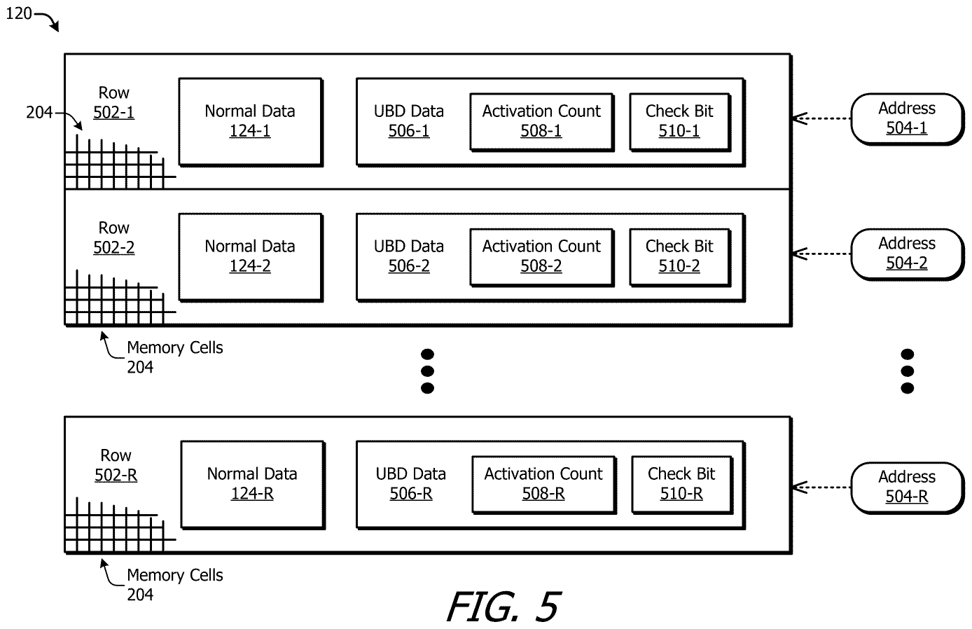

In other implementations, the memory die includes a third portion of memory cells that is designed to store usage-based disturbance data. Activation (or charging) of a first row of memory cells can sometimes negatively impact the integrity of the digital values stored in a second nearby row of memory cells. As the quantity of row activations increases, the likelihood of a negative impact on proximate rows increases. This phenomenon is referred to herein as usage-based disturbance. To track a quantity of row activations, usage-based-disturbance data can include an activation count for each row. The value stored in the activation count for one row can be used by the memory device to determine whether or when to perform a usage-based-disturbance mitigation operation to prevent a negative impact on the integrity of data in a proximate row. Usage-based disturbance is described further herein with reference to FIG. 5.

In some of the DRAM array implementations that include a third portion of memory cells that are designed to store usage-based disturbance data, the first and second portions of memory cells are designed to store normal data. Additionally or alternatively, the third portion of memory cells can have at least one property, such as a cost property or a performance property, that is the same as a property of the first portion. Thus, a DRAM array of a given memory die may include a first portion, a second portion, and a third portion in accordance with mixed-array DRAM architectures that are described herein.

In these manners, a single memory die can include a DRAM array with first and second portions of memory cells in which the first and second portions have at least one different property. The first and second portions can each store normal data that is accessible by a user, such as a host device or memory controller, in a regular (e.g., non-test) mode. In some implementations, the first portion of memory cells has a relatively higher performance property and a relatively higher cost property than the second portion of memory cells. The resulting mixed-array DRAM architecture with a given quantity of memory banks can provide comparable performance to other DRAM architectures that have a greater quantity of memory banks. Thus, implementing the schemes and techniques described herein can enable a memory device to provide higher performance with fewer memory banks thereby saving chip area and lowering power usage, which reduces manufacturing and operational costs.

### Example Operating Environments

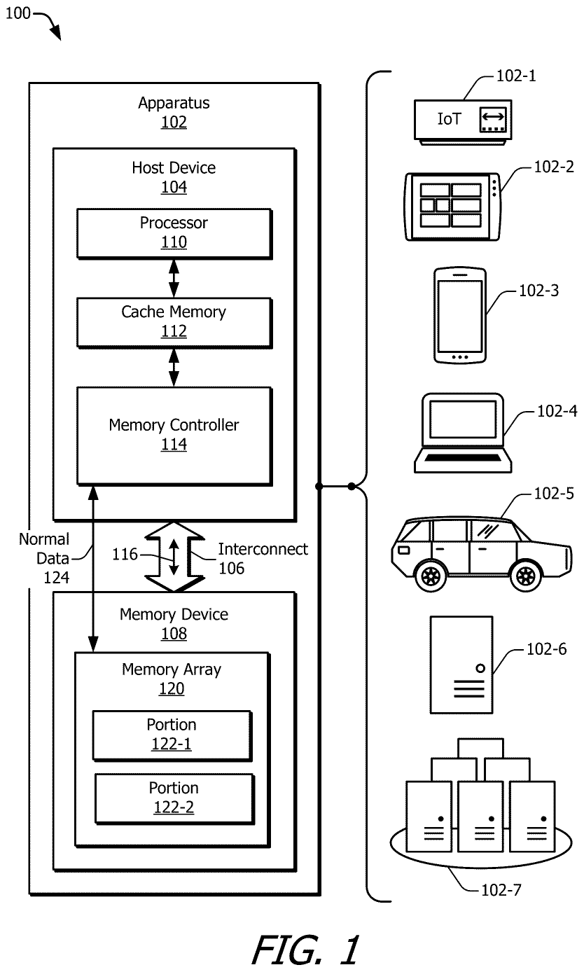

FIG. 1 illustrates, at 100 generally, an example operating environment including an apparatus 102 that can implement aspects of mixed-array dynamic random-access memory (DRAM) architecture. The apparatus 102 can include various types of electronic devices, including an internet-of-things (IoT) device 102-1, a tablet device 102-2, a smartphone 102-3, a notebook computer 102-4, a passenger vehicle 102-5, a server computer 102-6, or a server cluster 102-7. The server computer 102-6 or the server cluster 102-7 may be part of cloud computing infrastructure, a data center, or a portion thereof (e.g., a printed circuit board (PCB) or a data center rack or shelf thereof). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, medical device, or the electronic components of any computing device. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and at least one memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, a central processing unit (CPU), a graphics processing unit (GPU), a neural network engine or accelerator, an application-specific integrated circuit (ASIC), a field-programmable gate array (FPGA) integrated circuit (IC), a communications processor (e.g., a modem or baseband processor), and so forth.

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, reordering, and address remapping. The memory controller 114 can also forward to the processor 110 responses to the memory requests that are received from the external memory.

The host device 104 is operatively coupled, via the interconnect 106, to the memory device 108. In some examples, the memory device 108 is connected to the host device 104 via the interconnect 106 with an intervening buffer or cache. The memory device 108 may be operatively coupled to storage memory (not shown). The host device 104 can also be coupled, directly or indirectly via the interconnect 106, to the memory device 108 and the storage memory. The interconnect 106 and other interconnects (not illustrated in FIG. 1) can transfer information between two or more components of the apparatus 102. Examples of the interconnect 106 include a bus (e.g., a unidirectional or bidirectional bus), a switching fabric, or one or more wires that carry voltage-based or current-based signals. The interconnect 106 can propagate one or more communications 116, such as memory requests or memory responses, between the host device 104 and the memory device 108. For example, the host device 104 may transmit a memory request to the memory device 108 over the interconnect 106. Also, the memory device 108 may transmit a corresponding memory response to the host device 104 over the interconnect 106.

In other implementations, the interconnect 106 can be realized as a Compute Express Link® (CXL®) protocol link (CXL link). In other words, the interconnect 106 can comport with at least one CXL standard or protocol. The CXL link can provide an interface on top of the physical layer and electricals of a Peripheral Component Interconnect Express (PCIe) 5.0 physical layer, for instance. The CXL link can cause requests to and responses from the memory device 108 to be packaged as flits. In still other implementations, the interconnect 106 can be another type of link, including a PCIe 5.0 link. In this document, some terminology may draw from one or more identified standards or versions thereof, like a CXL standard or an LPDDR5 standard, for clarity. The described principles, however, are also applicable to memories and systems that comport with other memory and bus standards and other types of interconnects.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., lower than a level of the memory device 108). Memory at lower hierarchical levels may have a decreased speed but increased capacity relative to memory at higher hierarchical levels. Memory at lower hierarchical levels may also have a lower cost per bit.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory (not shown in FIG. 1). As another example, the apparatus 102 may include cache memory between the interconnect 106 and the memory device 108. Computer engineers can also include any of the described or illustrated components in distributed or shared memory systems.

This document describes with reference to FIG. 1 an example computing device or system architecture having at least one host device 104 coupled to a memory device 108. Computer engineers may implement the host device 104 and the various memories in multiple manners. In some cases, the host device 104 and the memory device 108 may be realized with separate packages that can be disposed on, or physically supported by, a printed circuit board (e.g., a rigid or flexible motherboard). The host device 104 and the memory device 108 may alternatively be integrated together on an integrated circuit or fabricated on separate integrated circuits and packaged together (e.g., with a stacked-die packaging architecture). The memory device 108 may also be coupled to multiple host devices 104 via one or more interconnects 106 and may respond to memory requests from two or more host devices 104. In such cases, each host device 104 may include a respective memory controller 114, or the multiple host devices 104 may share a memory controller 114.

Two or more memory components (e.g., modules, packages, dies, bank groups, or banks) can share the electrical paths or couplings of the interconnect 106. In some cases, the interconnect 106 can include at least one command-and-address bus (CA bus) and at least one data bus (DQ bus) (not shown). The command-and-address bus can transmit addresses and commands from the memory controller 114 of the host device 104 to the memory device 108, and this bus may exclude propagation of data. The data bus can propagate data bidirectionally between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM). Other examples of realizations for at least the memory device 108 include computational storage apparatuses, such as Computational Storage Devices (CSXs), Computational Storage Processors (CSPs), Computational Storage Drives (CSDs), and Computational Storage Arrays (CSAs). The memory device 108 may also include or be realized as processor-in-memory (PIM).

The memory device 108 can form at least part of the main memory of the apparatus 102. The memory device 108 may, however, form at least part of a cache memory, a storage memory, or a system-on-chip of the apparatus 102. The memory device 108 can include at least one memory array 120. In example implementations, the memory array 120 includes multiple portions 122-1, 122-2, 122-3, ... 122-P, with P representing an integer greater than one. In FIG. 1, two memory portions 122 are shown: a first portion 122-1 and a second portion 122-2. A third portion 122-3 is explicitly depicted in other figures, such as FIGS. 2, 4, 6-1, and 6-3. A memory array 120 can, however, have more than two or three portions 120 in accordance with mixed-array DRAM architecture as described herein.

In some implementations, the first portion 122-1 and the second portion 122-2 include at least one property that is different between the two portions. The property can be a performance property, a cost property, and so forth. Further, the first portion 122-1 and the second portion 122-2 can each be configured to store normal data 124. In example operations, the memory controller 114 can selectively store or write the normal data 124 in the first portion 122-1 or the second portion 122-2. Thus, the memory controller 114 can retrieve or read the normal data 124 from the selected portion, the first portion 122-1 or the second portion 122-2. The normal data 124 can be stored or retrieved via the interconnect 106 as at least one communication 116.

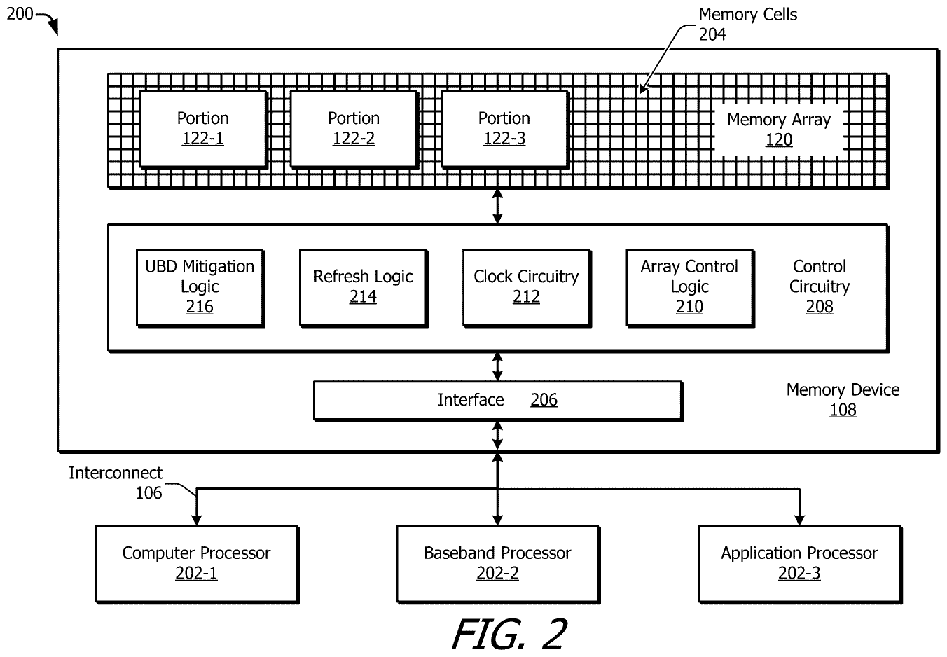

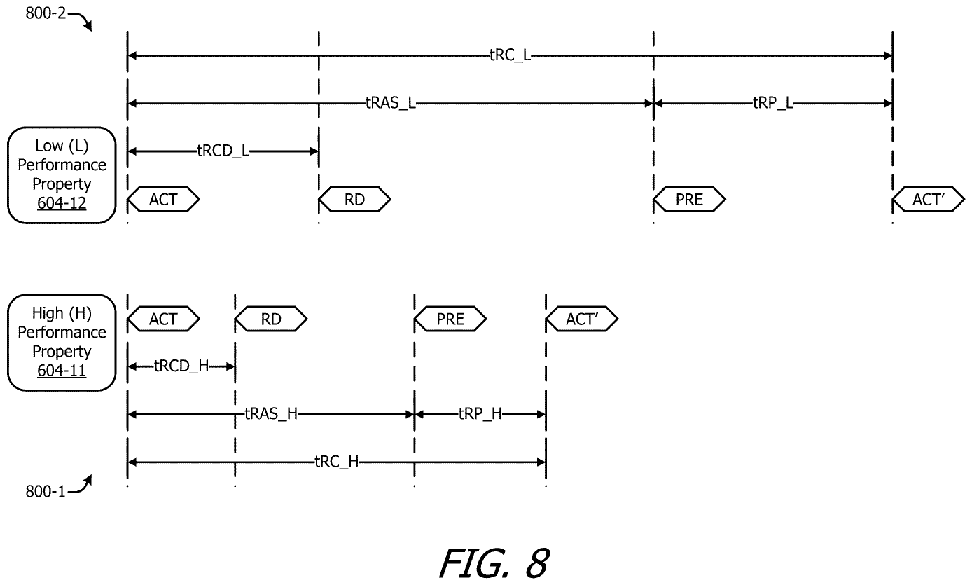

With reference below to FIGS. 6-1 to 6-3, this document describes examples of portions 122 of a DRAM array in terms of properties and layouts. FIGS. 7-1 and 7-2, which depict example bank-level implementations for first and second memory portions, are described thereafter. Comparative access timings for the first and second memory portions are described using FIG. 8. FIGS. 9-1 and 9-2 are referenced to describe example physical structures of the first and second memory portions that produce different properties. Prior to that description, however, example memory environments for mixed-array DRAM architecture are described. For example, this document next describes examples of the memory device 108 with reference to FIG. 2.

FIG. 2 illustrates an example computing system 200 that can implement aspects of mixed-array DRAM architecture with respect to a memory device 108. In some implementations, the computing system 200 includes at least one memory device 108, at least one interconnect 106, and at least one processor 202. The memory device 108 can include, or be associated with, at least one memory array 120, at least one interface 206, and control circuitry 208 (or periphery circuitry) that is operatively coupled to the memory array 120. The memory array 120 can include memory cells 204, including but not limited to memory cells of DRAM, SDRAM, three-dimensional (3D) stacked DRAM, DDR memory, LPDDR SDRAM, and so forth. The memory array 120 and the control circuitry 208 may be components on a single semiconductor die or on separate semiconductor dies. The memory array 120 or the control circuitry 208 may also be distributed across multiple dies. The control circuitry 208 may manage traffic on a bus that is separate from the interconnect 106, such as an internal bus of the memory device 108.

The control circuitry 208 can include various components that the memory device 108 can use to perform various operations. These operations can include communicating with other devices, managing memory performance, performing refresh operations (e.g., self-refresh operations or auto-refresh operations for DRAM), and performing memory read or write operations. For example, the control circuitry 208 can include at least one instance of array control logic 210, clock circuitry 212, refresh logic 214, or usage-based-disturbance mitigation logic 216 (UBD mitigation logic 216). The array control logic 210 can include circuitry that provides command decoding, address decoding, input/output functions, amplification circuitry, power supply management, power control modes, sense amplifying for data retrieval operations, write driving for data storage operations, and other functions.

The clock circuitry 212 can synchronize various memory components with one or more external clock signals provided over the interconnect 106, including a command-and-address clock or a data clock. The clock circuitry 212 can also or instead use an internal clock signal to synchronize memory components, and the clock circuitry 212 may provide timer functionality, such as for self-refresh operations. The refresh logic 214 can perform refresh operations on the memory array 120 (e.g., if the memory array 120 includes DRAM cells) in a self-refresh mode or an auto-refresh mode. The usage-based-disturbance mitigation logic 216 can perform usage-based-disturbance mitigation operations to protect data from the adverse effects of usage-based disturbance. Examples of usage-based-disturbance mitigation operations are described below with reference to FIG. 5. Although not explicitly shown in FIG. 2, the control circuitry 208 may include one or more mode registers to facilitate control by and/or communication with a processor 202.

The interface 206 can couple the control circuitry 208 or the memory array 120 directly or indirectly to the interconnect 106. In some implementations, the array control logic 210, the clock circuitry 212, the refresh logic 214, and the usage-based-disturbance mitigation logic 216 can be part of a single component (e.g., the control circuitry 208). In other implementations, one or more of the array control logic 210, the clock circuitry 212, the refresh logic 214, or the usage-based-disturbance mitigation logic 216 may be implemented as separate components. Such separate components can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and a processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus. Also, as discussed above with respect to FIG. 1, the interconnect 106 can include a CXL link or comport with at least one CXL standard. The CXL link can provide an interface or overlay on top of the physical layer and electricals of, e.g., a PCIe 5.0 physical layer.

In some aspects, the memory device 108 may be a “separate” component relative to the host device 104 (of FIG. 1) or any of the processors 202. Such a separate component can include a printed circuit board (PCB), memory card, memory stick, or memory module (e.g., a single in-line memory module (SIMM), dual in-line memory module (DIMM), or CXL memory module). Separate physical components may be located together within the same housing of an electronic device or may be distributed over a server rack, a data center, and so forth. Alternatively, the memory device 108 may be integrated with other physical components, including the host device 104 or the processor 202, by being combined together on a printed circuit board, in a single package, or in a system-on-chip (SoC).

As shown in FIG. 2, the one or more processors 202 may include a computer processor 202-1, a baseband processor 202-2, and/or an application processor 202-3 that are coupled to the memory device 108 through the interconnect 106. The processors 202 may include or form a part of a central processing unit (CPU), a graphics processing unit (GPU), a system-on-chip (SoC), an application-specific integrated circuit (ASIC), or a field-programmable gate array (FPGA). In some cases, a single processor can comprise multiple processing resources or cores, each dedicated to different functions (e.g., modem management, applications, graphics, security, artificial intelligence (AI), or central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). Further, a processor 202 may be realized as one that can communicate over a CXL-compatible interconnect. Accordingly, a respective processor 202 can include or be associated with a respective link controller. Alternatively, two or more processors 202 may access the memory device 108 using a shared link controller. In some of such cases, the memory device 108 may be implemented as a CXL-compatible memory device (e.g., as a CXL Type 3 memory expander), or another memory device that is compatible with a CXL protocol may also or instead be coupled to the interconnect 106.

In example implementations, the memory array 120 can include multiple portions 122-1, 122-2, 122-3, . . . 122-P. In FIG. 2, three memory portions 122 are shown: a first portion 122-1, a second portion 122-2, and a third portion 122-3. These three portions 122-1 to 122-3 are described below with reference to FIGS. 4 and 6-1 to 6-3. Next, however, this document describes an example implementation of a memory device 108 that can be realized as a memory module.

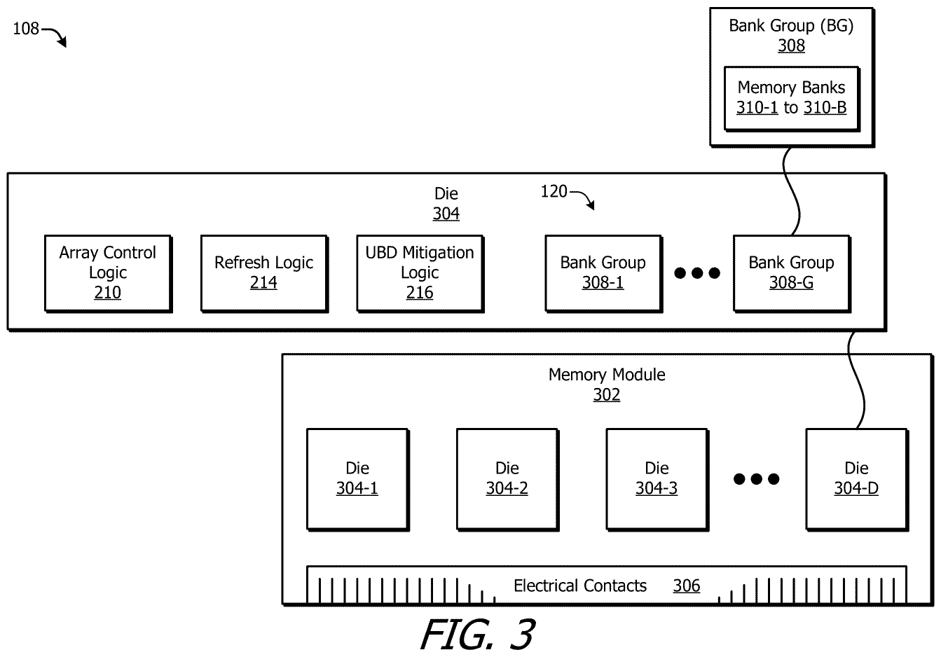

FIG. 3 illustrates an example memory device 108 in which aspects of mixed-array DRAM architecture can be implemented. As shown, the memory device 108 includes a memory module 302, which can include multiple dies 304. The memory module 302 is illustrated to include a first die 304-1, a second die 304-2, a third die 304-3, and a D^{th} die 304-D, with D representing a positive integer. The memory module 302 can be a SIMM or a DIMM, for instance. As another example, the memory module 302 can interface with other components via a bus interconnect (e.g., a Peripheral Component Interconnect Express (PCIe®) bus). The memory device 108 illustrated in FIGS. 1 and 2 can correspond, for example, to a die 304, to multiple dies (or dice) 304-1 through 304-D, or to a memory module 302 with two or more dies 304. As shown, the memory module 302 can include one or more electrical contacts 306 (e.g., pins) to interface the memory module 302 to other components.

The memory module 302 can be implemented in various manners. For example, the memory module 302 may include a printed circuit board, and the multiple dies 304-1 through 304-D may be mounted on, or otherwise attached to, the printed circuit board. The dies 304 (e.g., memory dies) may be arranged in a line or along two or more dimensions (e.g., to form a grid or array of dies). The dies 304 may have a similar size to each other or may have different sizes. Generally, each die 304 may be similar to another die 304 or may be different in size, shape, data capacity, or control circuitries. The dies 304 may also be positioned on a single side or on multiple sides of the memory module 302.

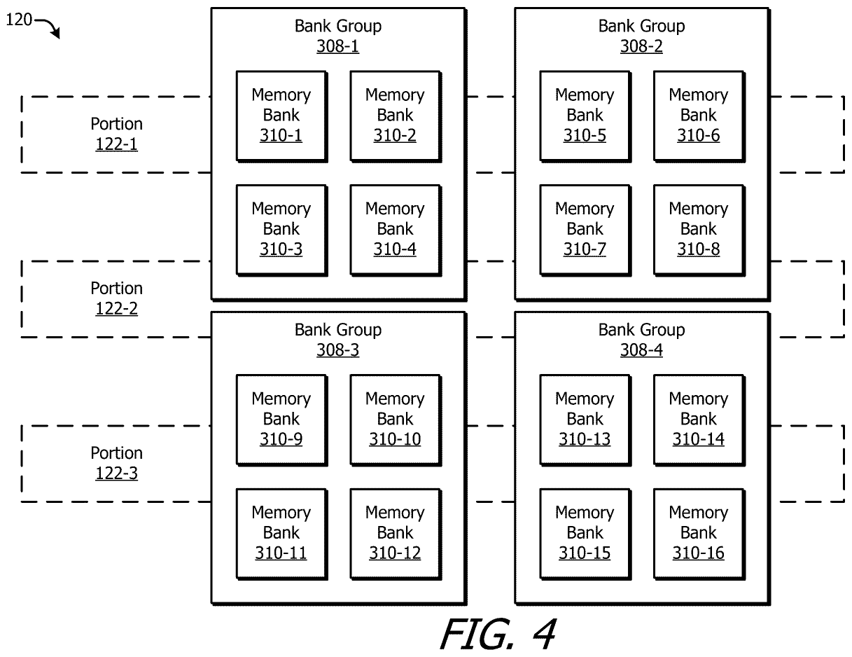

In example implementations, one or more of the dies 304-1 to 304-D include the memory array 120, the array control logic 210, the refresh logic 214, and the usage-based-disturbance mitigation logic 216. The memory array 120 includes multiple bank groups 308-1 . . . 308-G, with G representing a positive integer. Each bank group 308 includes at least two memory banks 310, such as multiple memory banks 310-1 . . . 310-B, with B representing a positive integer. In some implementations, the die 304 includes multiple instances of the UBD mitigation logic 216, each of which mitigates usage-based-disturbance across at least one of the memory banks 310. The die 304 can also include multiple instances of the refresh logic 214 or the array control logic 210, each of which performs respective operations for at least one respective corresponding memory bank 310. Generally, logic, or the circuitry thereof, can operate with respect to a single memory bank 310, multiple memory banks 310-1 to 310-B of a single bank group 308 (e.g., up to all memory banks of the bank group), multiple memory banks distributed across two or more bank groups, a single bank group 308, multiple bank groups 308-1 to 308-G, all banks on an IC chip (and thus all bank groups, if present), and so forth. An example arrangement of bank groups and memory banks is described next with reference to FIG. 4 and in the context of a relationship with multiple memory portions.

### Example Techniques And Hardware

FIG. 4 illustrates an example memory array 120 with multiple bank groups 308, multiple memory banks 310, and multiple memory portions 122 in which aspects of mixed-array DRAM architecture may be implemented. In the illustrated example, the memory array 120 has four bank groups 308-1 to 308-4 (G=4). These four bank groups include a first bank group 308-1, a second bank group 308-2, a third bank group 308-3, and a fourth bank group 308-4. The memory array 120 also includes 16 memory banks 310-1 to 310-16 (B=16). These 16 memory banks include a first memory bank 310-1, a second memory bank 310-2, . . . , a fifteenth memory bank 310-15, and a sixteenth memory bank 310-16. Other implementations, however, can include a different quantity of bank groups or memory banks. For instance, the memory array 120 may include 8, 24, 32, 64, or more memory banks 310 and may include 2, 8, 12, 16, 32, or more bank groups 308. Further, the memory banks 310 may not be separated into any bank groups (e.g., G=0).

In some implementations, each bank group 308 includes an equal quantity of memory banks 310. Thus, there are four memory banks 310 per bank group 308 in a scenario with 16 memory banks distributed across four bank groups. For instance, the first bank group 308-1 includes the first memory bank 310-1, the second memory bank 310-2, the third memory bank 310-3, and the fourth memory bank 310-4. Similarly, the third bank group 308-3 includes a ninth memory bank 310-9, a tenth memory bank 310-10, an eleventh memory bank 310-11, and a twelfth memory bank 310-12. In other implementations, however, bank groups 308 can have unequal quantities of memory banks 310, more or fewer than four memory banks 310, and so forth.

In example implementations, the memory array 120 includes multiple portions 122, such as two, three, or more portions 122. As shown in FIG. 4, the memory array 120 includes a first portion 122-1, a second portion 122-2, and a third portion 122-3. The portions 122 can be allocated to the memory banks 310 in any manner. In some cases, each memory bank 310 includes the first portion 122-1, the second portion 122-2, and the third portion 122-3, or each memory bank 310 includes the same two portions 122 but not three different portions 122. In other cases, each memory bank 310 is “dedicated” to a particular portion 122 such that each memory bank 310 includes only one portion 122. In still other cases, one memory bank 310 may include only one portion 122, another memory bank may include only one other portion 122, and two other memory banks may include different pairs of the three portions 122. Other allocations may alternatively be implemented, including with any quantity of two or more portions 122. Two example allocations of the portions 122 are depicted in FIGS. 7-1 and 7-2 and described below.

FIG. 5 illustrates example approaches to storing normal data 124 and usage-based-disturbance data 506 within rows 502 of a memory array 120 to support usage-based-disturbance mitigation. As illustrated, the memory array 120 includes multiple rows 502 of memory cells 204. For example, the memory array 120 can include multiple rows 502-1, 502-2, . . . , 502-R, where R represents a positive integer. Each row 502 is respectively associated with an address 504 (e.g., a row address, a memory row address, or a memory address) of multiple addresses 504-1, 504-2, . . . , 504-R. For example, a first row 502-1 has a first address 504-1, a second row 502-2 has a second address 504-2, and an R^{th} row 502-R has an R^{th} address 504-R.

In example implementations, each of the rows 502 can store normal data 124 within a first subset of the memory cells 204 associated with that row 502. The normal data 124 represents data that is read from or written to the memory device 108 during normal memory input/output operations (e.g., during normal read or write operations for user data). The normal data 124 can include, for example, data that is transmitted by the memory controller 114 and is written to one or more rows 502 of the memory array 120. In some implementations, in addition to the normal data 124, each of the rows 502 can store usage-based-disturbance data 506. The usage-based-disturbance data 506 can be stored within a second subset of the memory cells 204 associated with that row 502. Alternatively, the usage-based-disturbance data 506 can be stored separately from the rows 502. The usage-based-disturbance data 506 includes information that enables the usage-based-disturbance mitigation logic 216 (e.g., of FIGS. 2 and 3) to mitigate the potential effects of usage-based disturbance, which are described next.

To meet the demands for physically smaller memories, memory devices can be designed with higher chip densities for the memory cells 204 of a memory array 120. Increasing chip density, however, can increase the electromagnetic coupling between the memory cells 204 of proximate rows 502 due, at least in part, to a shrinking distance between these rows 502. With this undesired electromagnetic coupling (e.g., capacitive coupling), activation (or charging) of a first row 502-X (not shown) of memory cells 204 can sometimes negatively impact the integrity of the digital values stored in a second nearby row 502-(X+1) or 502-(X−1) of memory cells 204. This phenomenon is referred to as usage-based disturbance herein. Activation of the first row 502-X can generate interference, or crosstalk, that causes the second row, say 502-(X+1), to experience a voltage fluctuation. In some instances, this voltage fluctuation can cause a state, or value, of a memory cell 204 in the second row 502-(X+1) to be incorrectly determined by a sense amplifier. Consider an example in which a state of a memory cell 204 in the second row 502-(X+1) is a logical “1” (e.g., a high voltage). In this example, the voltage fluctuation can cause a sense amplifier to incorrectly determine the state of the memory cell 204 in the second row 502-(X+1) to be a logical “0” (e.g., a low voltage) instead of a logical “1.” Left unchecked, this interference can lead to memory errors or data loss within the memory device 108.

In some circumstances, a particular row 502-X of memory cells 204 is activated repeatedly in an unintentional or intentional manner, which can be part of a malicious act. Such a row 502-X that is repeatedly activated is referred to herein as an aggressor row. Consider, for instance, that memory cells 204 in a Zth row are subjected to repeated activation, which causes one or more memory cells 204 in a proximate row (e.g., an adjacent row) to change states. Here, a proximate row can include another row within a Z+1 row, which is an adjacent row; a Z+2 row; a Z−1 row, which is another adjacent row; and/or a Z−2 row. These proximate rows, which number four in this example, are referred to herein as victim rows.

The occurrence of usage-based disturbance can lead to the corruption or changing of contents within the affected row(s) 502 of memory. To combat the negative effects of usage-based disturbance, usage-based-disturbance mitigation logic 216 of a memory device 108 can perform usage-based-disturbance mitigation operations. For example, the usage-based-disturbance mitigation logic 216 can refresh one or more proximate rows 502, or at least one adjacent row 502, to recharge the capacitors that store the voltages that represent data. In other words, performing a refresh operation on a row 502 returns the memory cells 204 to their “full” correct charges. If the refresh operation is performed in a timely manner on a victim row, data loss because of usage-based-disturbance can be prevented. Whether a refresh operation on a victim row is timely can be determined, at least probabilistically, based on a quantity of activations of a corresponding aggressor row.

In some implementations, the usage-based-disturbance data 506 includes an activation count 508. With the activation count 508, the memory device 108 can keep track of the quantity of accesses or activations of the corresponding memory row 502. In example aspects, the usage-based-disturbance data 506 can also include a count of how many times a neighboring row (e.g., an adjacent or other proximate row) is refreshed in order to mitigate usage-based disturbance. Each of these counts provides an example mechanism by which the usage-based-disturbance mitigation logic 216 can monitor for usage-based disturbance and determine when to refresh victim rows to reduce the risk of usage-based disturbance corrupting data in the victim rows.

In the example shown in FIG. 5, the first row 502-1 stores first normal data 124-1 within a first subset of memory cells 204 of the first row 502-1 and stores first usage-based-disturbance data 506-1 within a second subset of memory cells 204 of the first row 502-1. The first usage-based-disturbance data 506-1 includes a first activation count 508-1, which represents a quantity of times the first row 502-1 has been activated since a last refresh. As another example, the second row 502-2 stores second normal data 124-2 within a first subset of memory cells 204 within the second row 502-2 and stores second usage-based-disturbance data 506-2 within a second subset of memory cells 204 within the second row 502-2. The second usage-based-disturbance data 506-2 includes a second activation count 508-2, which represents a quantity of times the second row 502-2 has been activated since a last refresh. Additionally, the R^{th} row 502-R stores R^{th} normal data 124-R within a first subset of memory cells 204 within the R^{th} row 502-R and stores R^{th} usage-based-disturbance data 506-R within a second subset of memory cells 204 within the R^{th} row 502-R. The R^{th} usage-based-disturbance data 506-R includes an R^{th} activation count 508-R, which represents a quantity of times the R^{th} row 502-R has been activated since a last refresh.

The usage-based-disturbance data 506 can also include information to support error detection or can be formatted (e.g., coded) in such a way as to support error detection. In this example, the usage-based-disturbance data 506 includes at least one check bit 510, such as a parity bit. In particular, the usage-based-disturbance data 506-1, 506-2, . . . , 506-R respectively includes a check bit 510-1, 510-2, . . . , 510-R. The at least one check bit 510 can be used to perform, for instance, an error-correcting-code (ECC) operation. Other implementations are also possible in which the usage-based-disturbance data 506 is coded in a manner that supports any given error detection test, such as an ECC check. Thus, the check bit 510, or other check bit(s) that are stored as part of the usage-based-disturbance data 506, can be used to check the accuracy or correctness of the activation count 508.

To protect against data loss because of usage-based-disturbance effects, refresh operations can be performed based on values stored as the activation counts 508. For example, the usage-based-disturbance mitigation logic 216 (e.g., of FIGS. 2 and 3) can determine whether a victim row 502 is to be refreshed using an activation count 508 of an aggressor row 502 and at least one mitigation threshold (not shown). If the activation count 508 exceeds the mitigation threshold, then the usage-based-disturbance mitigation logic 216 causes a refresh operation to be performed on the victim row or rows 502. For instance, the usage-based-disturbance mitigation logic 216 can queue the victim row 502 for refreshing due to usage-based-disturbance. The refresh operation may be performed by the refresh logic 214 or by logic associated with usage-based-disturbance mitigation.

In example implementations, some of the normal data 124 is stored as part of the first portion 122-1 (e.g., of FIG. 4), and other normal data 124 is stored as part of the second portion 122-2 (e.g., of FIG. 4). For instance, the normal data 124 of some rows 502 may correspond to the first portion 122-1, and the normal data 124 of other rows 502 may correspond to the second portion 122-2. Further, the usage-based-disturbance data 506 for one or more rows 502 may correspond to the third portion 122-3. Examples of such correspondences between data types (e.g., normal data 124 and usage-based-disturbance data 506) and memory portions 122-1, 122-2, and 122-3 are described next with reference to FIGS. 6-1 to 6-3.

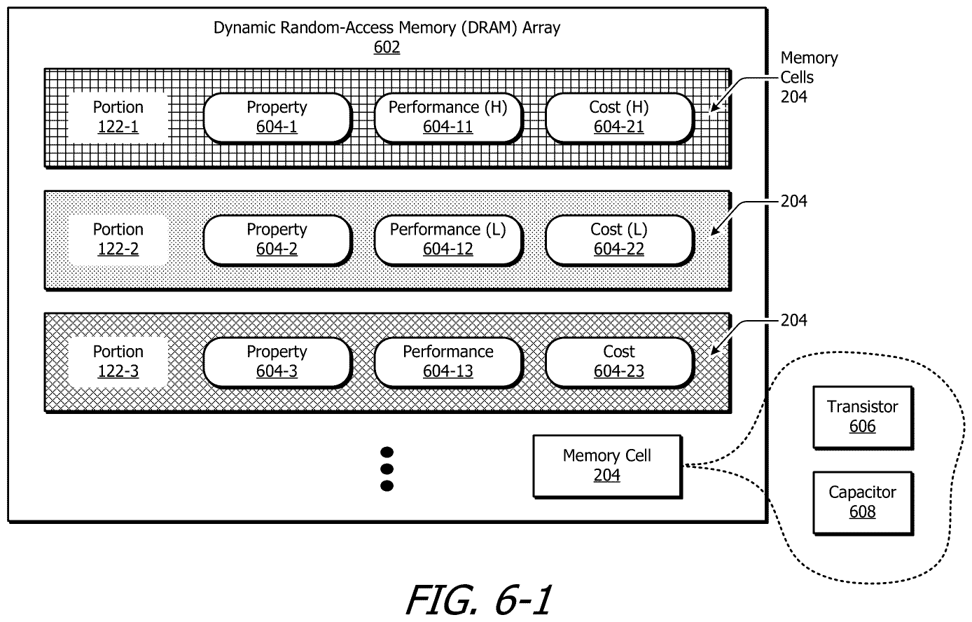

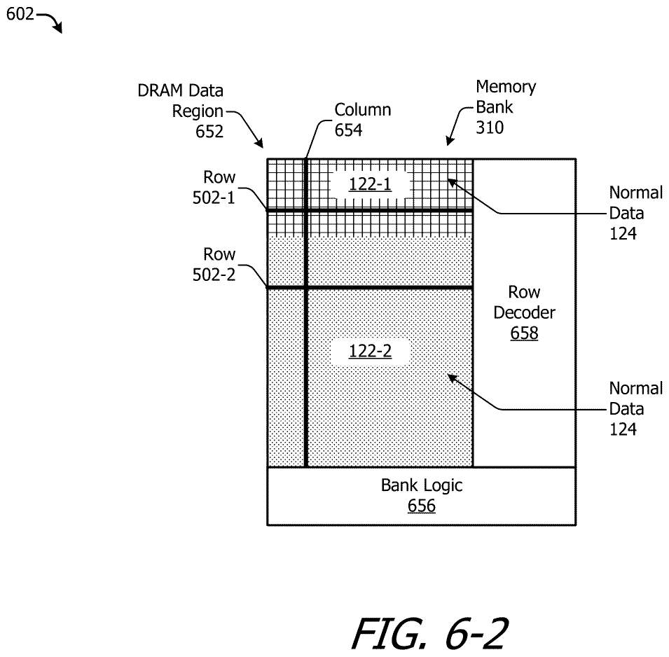

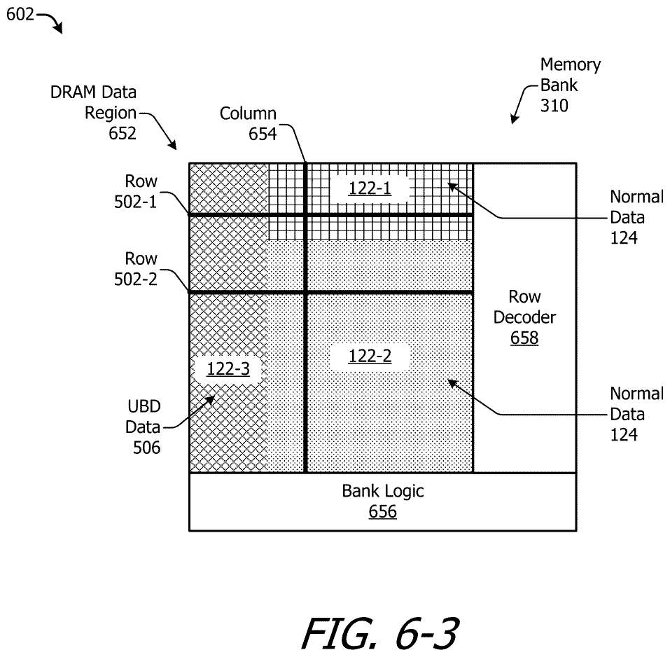

FIG. 6-1 is a schematic diagram illustrating an example dynamic random-access memory (DRAM) array 602 that includes a first portion 122-1 and a second portion 122-2 with each portion having at least one different property 604. The DRAM array 602 is an example of the memory array 120 (e.g., of FIGS. 1-5). As illustrated, the DRAM array 602 includes the first portion 122-1, the second portion 122-2, and a third portion 122-3. Each of the first portion 122-1, the second portion 122-2, and the third portion 122-3 includes multiple memory cells 204. For clarity, each portion 122 is filled with a respective pattern in certain figures, including FIGS. 6-1 to 6-3, 7-1, 7-2, 9-1, and 9-2. The first portion 122-1 has a horizontal/vertical crosshatch pattern, and the second portion 122-2 has a dotted pattern. The third portion 122-3 has a diagonal crosshatch pattern.

In example implementations, each portion 122 has, provides, or otherwise includes at least one corresponding property 604. Thus, the first portion 122-1 has a first property 604-1, and the second portion 122-2 has a second property 604-2. The third portion 122-3 has a third property 604-3. Other portions 122 (not shown) can also have respective properties 604. Each particular property 604 of a portion 122 can be the same as or different from the particular property 604 of another portion 122. The property 604 can be based, for example, on performance 604-1, cost 604-2, a combination thereof, and so forth. Examples of performance properties 604-1x include speed of access, latency, bandwidth, and so forth. Examples of cost properties 604-2x include price-per-bit, chip-area per-bit, and so forth.

The first property 604-1 of the first portion 122-1 corresponds to a relatively high (H) performance 604-11 and a relatively high (H) cost 604-21. The performance property 604-1x and the cost property 604-2x of one portion 122 can be relative to the performance property 604-1x and the cost property 604-2x of another portion 122. Here, the second property 604-2 of the second portion 122-2 corresponds to a relatively low (L) performance 604-12 and a relatively low (L) cost 604-22. Thus, the relatively high (H) performance property 604-11 of the first portion 122-1 is higher than the relatively low (L) performance property 604-12 of the second portion 122-2. Similarly, the relatively high (H) cost property 604-21 of the first portion 122-1 is higher than the relatively low (L) cost property 604-22 of the second portion 122-2.

The third property 604-3 of the third portion 122-3 can also include a performance property 604-13 and a cost property 604-23. The performance property 604-13 of the third portion 122-3 can be the same as or different than the performance properties 604-11 and 604-12 of the first and second portions 122-1 and 122-2. Similarly, the cost property 604-23 of the third portion 122-3 can be the same as or different than the cost properties 604-21 and 604-22 of the first and second portions 122-1 and 122-2. In an example that is described below with reference to FIG. 6-3, the performance property 604-13 of the third portion 122-3 can be the same as the performance property 604-11 of the first portion 122-1, and the cost property 604-23 of the third portion 122-3 can be the same as the cost property 604-21 of the first portion 122-1.

In some implementations, different properties 604 of different portions 122 can result from different structural characteristics. For example, a memory cell 204 or other memory array characteristics (e.g., bitline length) can vary between two or more memory portions 122. As shown in FIG. 6-1, each memory cell 204 can include at least one transistor 606 and at least one capacitor 608. The properties 604 can be varied in multiple ways. For example, a quantity of one or more transistors 606 or a quantity of one or more capacitors 608 per memory cell 204 can be varied (including varying the quantity of each). Additionally or alternatively, a length of the bitlines that couple memory cells 204 to sense amplifiers may be varied between memory portions 122. Examples of different physical structures are described below with reference to FIGS. 9-1 and 9-2.

FIG. 6-2 is a schematic diagram of a DRAM array 602 illustrating a memory bank 310 with an example layout of DRAM that includes the first portion 122-1 and the second portion 122-2. In example implementations, the memory bank 310 includes bank logic 656, a row decoder 658, and a DRAM data region 652. The bank logic 656 and the row decoder 658 are used to access the data stored in the DRAM data region 652. The DRAM data region 652 includes two portions: the first portion 122-1 and the second portion 122-2. Each of the first portion 122-1 and the second portion 122-2 can store normal data 124. In some implementations, each portion 122 includes at least one row 502 or at least part of at least one row. Further, a DRAM data region 652 of a memory bank 310 may include multiple instances of the first portion 122-1 or the second portion 122-2.

The DRAM data region 652 can be organized or addressed/accessed by a row 502 and a column 654. In the illustrated example, a first row 502-1 is part of the first portion 122-1. A second row 502-2 is part of the second portion 122-2. Accordingly, the first row 502-1 has one or more first properties 604-1 of the first portion 122-1, and the second row 502-2 has one or more second properties 604-2 of the second portion 122-2. The memory cells 204 of the first portion 122-1 have the first performance property 604-11 that is higher than the second performance property 604-12 of the memory cells 204 of the second portion 122-2. Data stored in the memory cells 204 of the first row 502-1 can therefore be accessed (e.g., written or read) more quickly than the data stored in the memory cells 204 of the second row 502-2.

FIG. 6-3 is a schematic diagram illustrating a memory bank 310 of a DRAM array 602 with an example layout of DRAM that includes the first portion 122-1, the second portion 122-2, and a third portion 122-3. The example memory bank 310 of FIG. 6-3 is similar to the example memory bank 310 of FIG. 6-2. However, in the example implementations corresponding to FIG. 6-3, the third portion 122-3 is included as part of the memory bank 310. In some cases, the third portion 122-3 can be part of the DRAM data region 652 (as shown). In other cases, the third portion 122-3 may be separate from the DRAM data region 652 or part of a DRAM data region 652 that is different from the DRAM data region 652 that includes the first and second portions 122-1 and 122-2.

In the illustrated example, the third portion 122-3 includes usage-based-disturbance data 506. The first and second portions 122-1 and 122-2 include normal data 124. Thus, each row 502 can include normal data 124 and usage-based-disturbance data 506 as shown in FIG. 5. For instance, the first row 502-1 can include usage-based-disturbance data 506 as part of the third portion 122-3 and normal data 124 as part of the first portion 122-1. The second row 502-2 can include usage-based-disturbance data 506 as part of the third portion 122-3 and normal data 124 as part of the second portion 122-2.

In some implementations, the first portion 122-1 and the third portion 122-3 can include the same realizations or values of the first and third properties 604-1 and 604-3 of FIG. 6-1. To do so, the first portion 122-1 and the third portion 122-3 may have one or more of the same physical structures, such as those described below with reference to FIGS. 9-1 and 9-2. For instance, a high performance property 604-13 can enable an activation count 508 (e.g., of FIG. 5) to be updated during a refresh operation without lengthening the duration of the refresh operation.

FIGS. 7-1 and 7-2 are schematic diagrams illustrating example allocations of memory portions 122 at an array-level across multiple memory banks 310 of a DRAM array 602. In these examples, the DRAM array 602 includes 16 memory banks 310-1, 310-2, . . . , 310-15, and 310-16. Thus, the first portion 122-1 and the second portion 122-2 are allocated across the 16 memory banks 310-1 to 310-16.

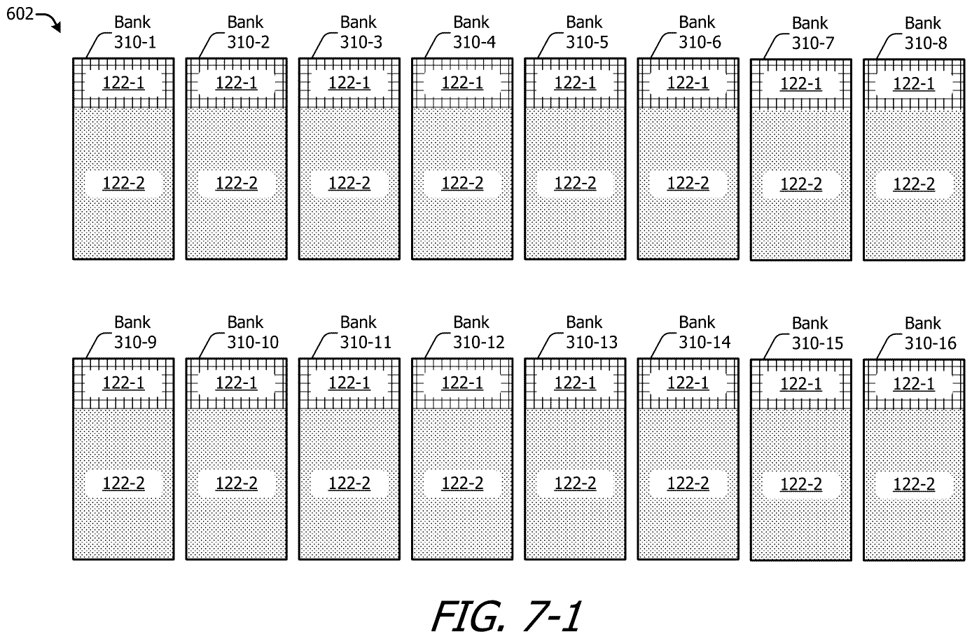

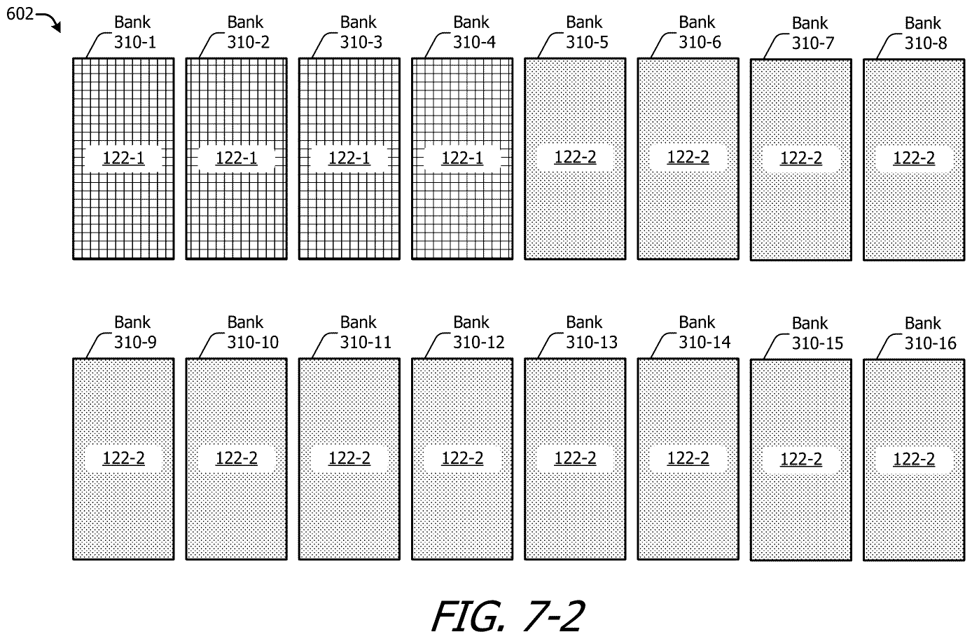

FIG. 7-1 is a schematic diagram illustrating a first example allocation of the first and second portions 122-1 and 122-2 of the DRAM array 602 across the 16 memory banks 310-1 to 310-16. In example implementations as shown for the first example allocation, each memory bank 310 includes memory cells 204 of the first portion 122-1 and memory cells 204 of the second portion 122-2. Although the memory portions 122 are depicted as having the same relative proportions or percentages per memory bank 310, these proportions may instead vary across two or more memory banks 310. By way of example only, within a given memory bank 310 or across an entire DRAM array 602, the first portion 122-1 may occupy a given percentage of the total memory array that is dedicated to normal data 124 relative to the percentage allocated to the second portion 122-2. This percentage for the first portion 122-1 with the high (H) performance property 604-11 can be one percent (1%), two percent (2%), three percent (3%), five percent (5%), seven and a half percent (7.5%), ten percent (10%), fifteen percent (15%), or even more.

FIG. 7-2 is a schematic diagram illustrating a second example allocation of the first and second portions 122-1 and 122-2 of the DRAM array 602 across the 16 memory banks 310-1 to 310-16. In example implementations as shown for the second example allocation, each memory bank 310 includes memory cells 204 of the first portion 122-1 or memory cells 204 of the second portion 122-2, but not memory cells 204 of the first portion 122-1 and second portion 122-2. In other words, each memory bank 310 is dedicated to exactly one portion 122, or each memory bank 310 has memory cells 204 of only one portion 122 (e.g., a single portion 122), but not memory cells 204 of multiple portions 122.

Generally, at least one memory bank 310, such as the second memory bank 310-2 can have memory cells 204 of the first portion 122-1 but lack memory cells 204 of the second portion 122-2. At least one other memory bank 310, such as the seventh memory bank 310-7, can have memory cells 204 of the second portion 122-2 but lack memory cells 204 of the first portion 122-1. Although the allocations of memory portions 122 are homogenous in FIGS. 7-1 and 7-2, the allocations may instead be varied across two or more memory banks 310. For instance, a first memory bank 310 may be dedicated to a first portion 122-1, a second memory bank 310 may be dedicated to a second portion 122-2, and a third memory bank 310 may have memory cells 204 of the first portion 122-1 and of the second portion 122-2.

Further, each memory bank 310 may have one or more other portions 122 included along with the portion 122 or the portions 122 that are depicted in FIGS. 7-1 and 7-2. For example, a third portion 122-3 can be included in each memory bank 310, or in at least some of the total quantity of memory banks 310. In at least some implementations for which the third portion 122-3 is realized to store usage-based-disturbance data 506, each memory bank 310 can include the usage-based-disturbance data 506 of a third portion 122-3. For example, usage-based-disturbance data 506 can be included as part of each row 502, whether the row 502 has memory cells 204 of the first portion 122-1 or of the second portion 122-2.

FIG. 8 depicts example first and second timing diagrams 800-1 and 800-2 for respectively accessing the first and second portions 122-1 and 122-2 of a memory array 120, such as a DRAM array 602. Each timing diagram includes an activation command (ACT), a read command (RD), a precharge command (PRE), and another, subsequent activation command (ACT′). The first timing diagram 800-1 corresponds to a high (H) performance property 604-11 for the first portion 122-1. The second timing diagram 800-2 corresponds to a low (L) performance property 604-12 for the second portion 122-2.

Each timing diagram 800 depicts multiple access timings. The timings that correspond to the low (L) performance property 604-12 include an extension “_L.” The timings corresponding to the high (H) performance property 604-11 include an extension “_H.” The time between the activation command (ACT) and the read command (RD) is the row-address to column-address delay time, or row-address-strobe (RAS) to column-address-strobe (CAS) delay: tRCD. This reflects the minimum time (e.g., the number of clock cycles) between opening a row and accessing the columns thereof. The time between the activation command (ACT) and the precharge command (PRE) is the row active time, or row address strobe: tRAS. This reflects the minimum time between issuing the row active command and issuing the precharge command.

The time between the precharge command (PRE) and the next or subsequent activation command (ACT′) is the row precharge time, or RAS precharge time: tRP. This reflects the time between disabling access to one row and beginning access to another row. The time between the activation command (ACT) and the next or subsequent activation command (ACT′) is the row cycle time, or array timing: tRC. Here, tRC=tRAS+tRP.

A comparison of the first timing diagram 800-1 to the second timing diagram 800-2 reveals that each of the timings are shorter for the first portion 122-1 with the high (H) performance property 604-11 than for the second portion 122-2 with the low (L) performance property 604-12. For example, the high-performance row cycle time tRC_H is shorter than the low-performance row cycle time tRC_L. Thus, the low-performance row cycle time tRC_L corresponds to a relatively lower performance property 604-12 than does the high-performance row cycle time tRC_H that corresponds to the relatively higher performance property 604-11. Generally, shorter access timings result in lower latency and higher bandwidth for a memory. Accordingly, data stored in the memory cells 204 of the first portion 122-1 with the high (H) performance property 604-11 can be returned by the memory device faster than data stored in the second portion 122-2.

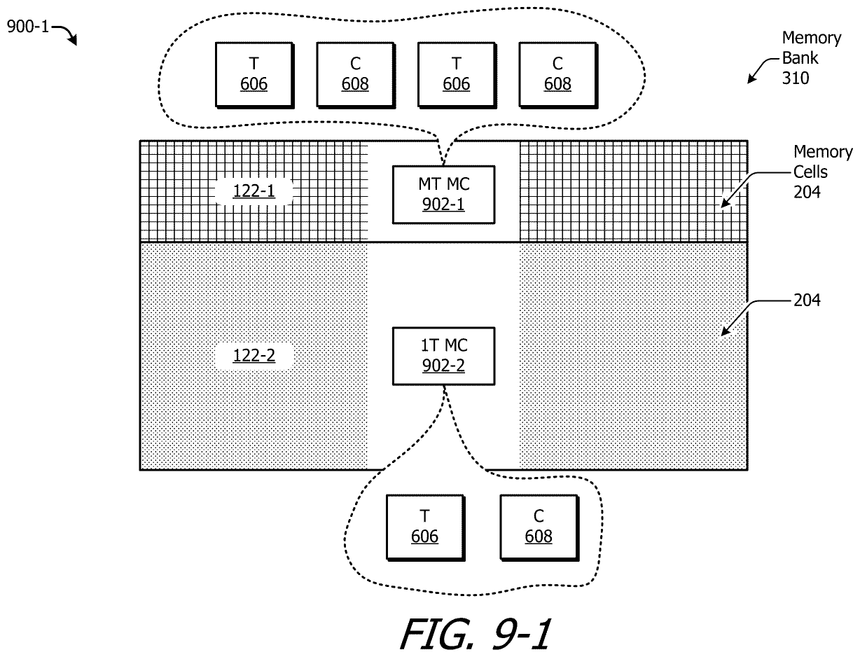

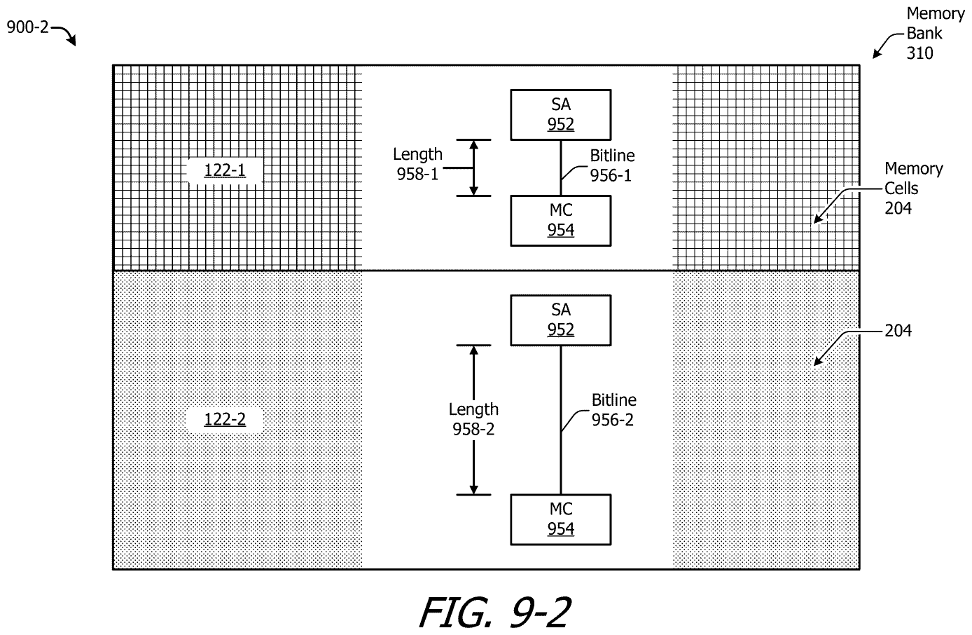

FIG. 9-1 illustrates a first example approach 900-1 to implementing first and second portions 122-1 and 122-2 of a memory array to produce a mixed-array DRAM architecture having at least one different property 604 across the first and second portions 122-1 and 122-2. The first example approach 900-1 is described in terms of a memory bank 310 that includes the first portion 122-1 and the second portion 122-2. The principles, however, are applicable to other implementations, such as those in which memory banks 310 do not include first and second portions 122-1 and 122-2, those without multiple memory banks 310, those with more than two different portions 122 in a memory bank 310, and so forth. The different properties 604 can include or result from structural differences, such as those that produce different performance properties 604-1x or different cost properties 604-2x.

In example implementations, the first portion 122-1 includes a multi-transistor memory cell 902-1 (MT memory cell 902-1), and the second portion 122-2 includes a one-transistor memory cell 902-2 (1T memory cell 902-2). In some cases, the one-transistor memory cell 902-2 includes exactly one transistor 606. The one-transistor memory cell 902-2 can also include exactly one capacitor 608. The transistor 606 of the one-transistor memory cell 902-2 provides access to the charge level stored on the capacitor 608 of the one-transistor memory cell 902-2 for reading and writing. The multi-transistor memory cell 902-1 and the one-transistor memory cell 902-2 can correspond to the memory cells 204 that are described herein and depicted in multiple figures.

The multi-transistor memory cell 902-1 includes multiple transistors 606 and at least one capacitor 608. The multiple transistors 606 of the multi-transistor memory cell 902-1 provide access to the charge level stored on the at least one capacitor 608 of the multi-transistor memory cell 902-1. With two transistors 606, the multi-transistor memory cell 902-1 can access the at least one capacitor 608 more quickly in terms of reading or writing the stored voltage level as compared to with the single transistor 606 of the one-transistor memory cell 902-2. This enables the multi-transistor memory cell 902-1 of the first portion 122-1 of memory cells 204 to provide a higher performance property 604-11 than the one-transistor memory cell 902-2 of the second portion 122-2 of memory cells 204 provides at the relatively lower performance property 604-12.

In some cases, the multi-transistor memory cell 902-1 includes exactly two transistors 606. However, the multi-transistor memory cell 902-1 may include three or more transistors 606. Also, in example aspects, the multi-transistor memory cell 902-1 can include one capacitor 608 per transistor 606. The additional transistor(s) 606 or capacitor(s) 608 of the multi-transistor memory cell 902-1 do occupy more area than the single transistor 606 and single capacitor 608 of the one-transistor memory cell 902-2. Accordingly, the first portion 122-1 is associated with a higher cost property 604-21 as compared to the lower cost property 604-22 of the second portion 122-2.

In some implementations, a third portion 122-3 of memory cells 204 (not shown in FIG. 9-1) can also be fabricated using the multi-transistor memory cells 902-1. Thus, the higher performance property and the higher cost property, relative to that of the second portion 122-2, can also be associated with the third portion 122-3. If usage-based-disturbance data 506 is stored in the third portion 122-3, accessing the usage-based-disturbance data 506 can be faster like is shown for the timing diagram 800-1 (of FIG. 8) relative to the timing diagram 800-2.

FIG. 9-2 illustrates a second example approach 900-2 to implementing first and second portions 122-1 and 122-2 of a memory array to produce a mixed-array DRAM architecture having at least one different property 604 across the first and second portions 122-1 and 122-2. The second example approach 900-2 is described in terms of a memory bank 310 that includes the first portion 122-1 and the second portion 122-2. The principles, however, are applicable to other implementations, as noted above regarding FIG. 9-1. The different properties 604 can include or result from structural differences, such as those that produce different performance properties 604-1x or different cost properties 604-2x. The memory cells 954 of the first and second portions 122-1 and 122-2 can correspond to the memory cells 204 that are described herein and depicted in various figures.

In example implementations, bitline lengths 958 are different in the first portion 122-1 as compared to in the second portion 122-2. Each bitline 956 extends between a sense amplifier 952 and at least one memory cell 954. The physical metal of the bitline may extend between the sense amplifier 952 and multiple memory cells 954. However, the length 958 of a bitline 956, as used herein, refers to the length 958 between the sense amplifier 952 and a given individual memory cell 954. With a shorter length 958 of the bitline 956, the capacitive load along the bitline 956 is lower, and a signal can traverse the bitline 956 more quickly. This enables relatively faster access to the data stored in memory cells 954 that are coupled to bitlines 956 via relatively shorter lengths 958.

In some implementations, the first portion 122-1 of memory cells 204 includes a memory cell 954 that is coupled to a corresponding sense amplifier 952 via a first bitline 956-1. The second portion 122-2 of memory cells 204 includes a memory cell 954 that is coupled to a corresponding sense amplifier 952 via a second bitline 956-2. A first length 958-1 of the first bitline 956-1 is shorter than a second length 958-2 of the second bitline 956-2. This can be accomplished, for example, by including additional sense amplifiers 952 in the first portion 122 relative to the total quantity of memory cells 954. In other words, each sense amplifier 952 of the first portion 122-1 may be coupled to, and may serve, fewer memory cells 954 than each sense amplifier 952 of the second portion 122-2.

In a memory array, or portion 122 thereof, each sense amplifier 952 can be coupled to multiple memory cells 954 that are positioned or disposed at different distances to the sense amplifier 952. The bitlines 956, even within a given portion 122, vary based on how far the memory cell 954 is disposed from the corresponding sense amplifier 952. In at least some of such cases, the multiple memory cells 954 of the first portion 122-1 are coupled to one or more corresponding sense amplifiers 952 via multiple first bitlines 956-1. Similarly, the multiple memory cells 954 of the second portion 122-2 are coupled to one or more corresponding sense amplifiers 952 via multiple second bitlines 956-2. To create a speed of access difference between the first portion 122-1 and the second portion 122-2, a first average length 958-1′ of the multiple first bitlines 956-1 is fabricated to be less than some percentage of a second average length 958-2′ of the multiple second bitlines 956-2. This percentage may be, for example, fifty percent (50%), forty percent (40%), thirty percent (30%), twenty percent (20%), ten percent (10%), or even less than the second average length 958-2′ of the multiple second bitlines 956-2.

### Example Methods

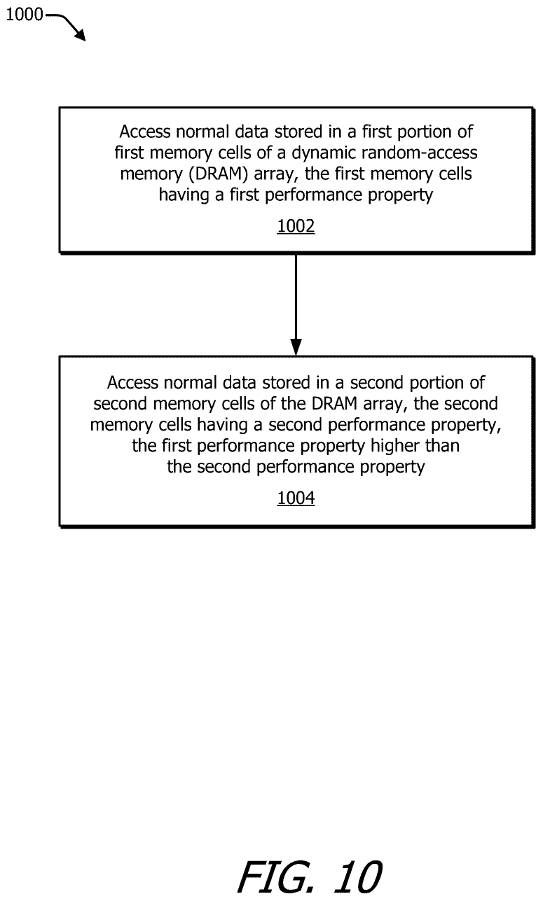

This subsection describes example methods for implementing mixed-array dynamic random-access memory (DRAM) architecture with reference to the flow diagram of FIG. 10. These descriptions may also refer to components, entities, and other aspects depicted in FIGS. 1 to 9-2, but by way of example only. The described methods are not necessarily limited to performance by one entity present or operating on one device. In particular, but by way of example only, the description of FIG. 7-2 provides examples of implementations that span multiple banks and associated access circuitry, such as bank logic 656 (of FIGS. 6-2 and 6-3).

FIG. 10 illustrates a flow diagram 1000, which includes operations 1002 and 1004, for implementing aspects of mixed-array DRAM architecture for a memory device, such as a memory die or a memory module with multiple memory dies. In aspects, operations of the method 1000 can be implemented by array control logic 210, bank logic 656, a row decoder 658, combinations thereof, and so forth as described with reference to FIGS. 1 to 9-2.

At block 1002, normal data stored in a first portion of first memory cells of a dynamic random-access memory (DRAM) array is accessed, with the first memory cells having a first performance property. For example, normal data 124 stored in a first portion 122-1 of first memory cells 204 of a DRAM array 602 can be accessed, with the first memory cells having a first performance property 604-11. The array control logic 210 may access the normal data 124 stored in the first portion 122-1 of a memory bank 310. The first performance property 604-11 may be, for instance, a speed of accessing the first memory cells of the first portion 122-1. The speed of accessing may be at least partly dependent on how many transistor(s) 606 are present in each multi-transistor memory cell 902-1 or how long the length 958-1 of each bitline 956-1 is between a sense amplifier 952 and a memory cell 954 of the first portion 122-1.

At block 1004, normal data stored in a second portion of second memory cells of the DRAM array is accessed, with the second memory cells having a second performance property, and the first performance property being higher than the second performance property. For example, normal data 124 stored in a second portion 122-2 of second memory cells 204 of the DRAM array 602 can be accessed. Here, the second memory cells 204 have a second performance property 604-12, and the first performance property 604-11 is higher (e.g., faster accessing) than the second performance property 604-12. The array control logic 210 may access the normal data 124 stored in the second portion 122-2 of the memory bank 310. The second performance property 604-12 may be, for instance, a speed of accessing the second memory cells of the second portion 122-2. The speed of accessing may be at least partly dependent on the presence of exactly one transistor 606 in each one-transistor memory cell 902-2 or how long the length 958-2 of each bitline 956-2 is between a sense amplifier 952 and a memory cell 954 of the second portion 122-2.

In some implementations, usage-based-disturbance data stored in a third portion of third memory cells of the DRAM array is accessed. Here, the third memory cells have a third performance property, and the first performance property is substantially the same as the third performance property. For example, array control logic 210 can access usage-based-disturbance data 506 stored in a third portion 122-3 of third memory cells of the DRAM array 602. The third memory cells of the third portion 122-3 can have a third performance property 604-13, and the first performance property 604-11 can be substantially the same as the third performance property 604-13. Here, two performance properties 604-1x may be substantially the same as each other if each has a same quantity of transistors, if the average bitline lengths are within ten percent (10%) of each other, and so forth.

For the figures and operations described above, the orders in which the operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-logic circuitry or a processor in conjunction with a memory), firmware, software, or some combination thereof. The methods may be realized using one or more of the apparatuses or components shown in FIGS. 1 to 9-2, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of mixed-array DRAM architecture are described:
Example 1: An apparatus comprising:
a memory die comprising a dynamic random-access memory (DRAM) array, the DRAM array comprising:
   a first portion of memory cells having a first performance property and configured to store normal data; and
   a second portion of memory cells having a second performance property and configured to store normal data, the first performance property higher than the second performance property.

Example 2: The apparatus of example 1, or any other example(s) described herein, wherein:
a performance property corresponds to speed of access of the DRAM array; and
the first performance property corresponds to a faster speed of access than the second performance property.

Example 3: The apparatus of example 2, or any other example(s) described herein, wherein:
the first performance property comprises a first row cycle time (tRC);
the second performance property comprises a second row cycle time; and
the first row cycle time is shorter than the second row cycle time.

Example 4: The apparatus of example 1, or any other example(s) described herein, wherein:
the memory cells of the first portion have a first cost property;
the memory cells of the second portion have a second cost property; and
the first cost property is higher than the second cost property.

Example 5: The apparatus of example 1, or any other example(s) described herein, wherein:
the first portion of memory cells comprises multiple first memory cells, each first memory cell of the multiple first memory cells comprising multiple transistors; and
the second portion of memory cells comprises multiple second memory cells, each second memory cell of the multiple second memory cells comprising exactly one transistor.

Example 6: The apparatus of example 5, or any other example(s) described herein, wherein:
each first memory cell of the multiple first memory cells comprises exactly two transistors.

Example 7: The apparatus of example 5, or any other example(s) described herein, wherein:
each first memory cell of the multiple first memory cells comprises multiple capacitors; and
each second memory cell of the multiple second memory cells comprises exactly one capacitor.

Example 8: The apparatus of example 1, or any other example(s) described herein, wherein:
the first portion of memory cells comprises multiple first memory cells, a first memory cell of the multiple first memory cells coupled to a corresponding first sense amplifier via a first bitline;
the second portion of memory cells comprises multiple second memory cells, a second memory cell of the multiple second memory cells coupled to a corresponding second sense amplifier via a second bitline; and
a first length of the first bitline is shorter than a second length of the second bitline.

Example 9: The apparatus of example 8, or any other example(s) described herein, wherein:
the multiple first memory cells are coupled to one or more corresponding first sense amplifiers via multiple first bitlines;
the multiple second memory cells are coupled to one or more corresponding second sense amplifiers via multiple second bitlines; and
a first average length of the multiple first bitlines is less than fifty percent (50%) of a second average length of the multiple second bitlines.

Example 10: The apparatus of example 1, or any other example(s) described herein, wherein:
the DRAM array comprises multiple memory banks;
at least one memory bank of the multiple memory banks comprises memory cells of the first portion but lacks memory cells of the second portion; and
at least one other memory bank of the multiple memory banks comprises memory cells of the second portion but lacks memory cells of the first portion.

Example 11: The apparatus of example 1, or any other example(s) described herein, wherein:
the DRAM array comprises multiple memory banks; and
at least one memory bank of the multiple memory banks comprises memory cells of the first portion and memory cells of the second portion.

Example 12: The apparatus of example 11, or any other example(s) described herein, wherein:
all memory banks of the DRAM array comprise memory cells of the first portion and memory cells of the second portion.

Example 13: The apparatus of example 11, or any other example(s) described herein, wherein:
a ratio of a first area occupied by the first portion of memory cells to a second area occupied by the second portion of memory cells in the at least one memory bank is less than fifteen percent (15%).

Example 14: The apparatus of example 1, or any other example(s) described herein, wherein:
each memory cell of the memory cells of the first portion comprises at least one transistor and at least one capacitor; and
each memory cell of the memory cells of the second portion comprises at least one transistor and at least one capacitor.

Example 15: The apparatus of example 14, or any other example(s) described herein, wherein:
the memory cells of the first portion and the memory cells of the second portion are fabricated using the same process technology.

Example 16: The apparatus of example 14, or any other example(s) described herein, wherein:
the memory cells of the first portion are configured to store a bit of data in each memory cell of the first portion by applying a charge to the at least one capacitor using the at least one transistor of each memory cell of the first portion; and
the memory cells of the second portion are configured to store a bit of data in each memory cell of the second portion by applying a charge to the at least one capacitor using the at least one transistor of each memory cell of the second portion.

Example 17: The apparatus of example 1, or any other example(s) described herein, wherein:
the normal data comprises user data.

Example 18: The apparatus of example 1, or any other example(s) described herein, wherein the DRAM array comprises:
a third portion of memory cells configured to store usage-based disturbance data.

Example 19: The apparatus of example 18, or any other example(s) described herein, wherein:
the third portion of memory cells has the first performance property.

Example 20: The apparatus of example 18, or any other example(s) described herein, wherein:
the first portion of memory cells comprises multiple first memory cells, each first memory cell of the multiple first memory cells comprising multiple transistors;
the second portion of memory cells comprises multiple second memory cells, each second memory cell of the multiple second memory cells comprising exactly one transistor; and
the third portion of memory cells comprises multiple third memory cells, each third memory cell of the multiple third memory cells comprising multiple transistors.

Example 21: An apparatus comprising:
a memory die comprising a dynamic random-access memory (DRAM) array, the DRAM array comprising:
   a first portion of first memory cells configured to store normal data, each first memory cell comprising multiple transistors; and
   a second portion of second memory cells configured to store normal data, each second memory cell comprising exactly one transistor.

Example 22: The apparatus of example 21, or any other example(s) described herein, wherein the DRAM array comprises:
a third portion of third memory cells configured to store usage-based disturbance data, each third memory cell comprising multiple transistors.

Example 23: The apparatus of example 22, or any other example(s) described herein, wherein the usage-based-disturbance data comprises:
one or more activation counts, each activation count indicative of a quantity of times a corresponding row has been activated.

Example 24: The apparatus of example 22, or any other example(s) described herein, wherein the DRAM array comprises:
multiple rows, each row of the multiple rows comprising:
   third memory cells of the third portion; and
   first memory cells of the first portion or second memory cells of the second portion.

Example 25: The apparatus of example 24, or any other example(s) described herein, wherein the DRAM array comprises:
a memory bank including the multiple rows;
a first row of the multiple rows comprising:
   third memory cells of the third portion; and
   first memory cells of the first portion; and
a second row of the multiple rows comprising:
   third memory cells of the third portion; and
   second memory cells of the second portion.

Example 26: A method for a memory die, or any other example(s) described herein, the method comprising:
accessing normal data stored in a first portion of first memory cells of a dynamic random-access memory (DRAM) array, the first memory cells having a first performance property; and
accessing normal data stored in a second portion of second memory cells of the DRAM array, the second memory cells having a second performance property, the first performance property higher than the second performance property.

Example 27: The method of example 26, or any other example(s) described herein, further comprising:
accessing usage-based-disturbance data stored in a third portion of third memory cells of the DRAM array, the third memory cells having a third performance property, the first performance property substantially the same as the third performance property.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### Conclusion

Although aspects of implementing mixed-array dynamic random-access memory (DRAM) architecture have been described in language specific to certain features and/or methods, the subject of the appended claims is not necessarily limited to the specific features or methods described. Rather, the specific features and methods are disclosed as a variety of example implementations for mixed-array DRAM architecture.

What is claimed is:

1. An apparatus comprising:
a memory die comprising a dynamic random-access memory (DRAM) array, the DRAM array comprising:
a first portion of memory cells having a first performance property and configured to store normal data; and
a second portion of memory cells having a second performance property and configured to store normal data, the first performance property higher than the second performance property.

2. The apparatus of claim 1, wherein:
a performance property corresponds to speed of access of the DRAM array; and
the first performance property corresponds to a faster speed of access than the second performance property.

3. The apparatus of claim 2, wherein:
the first performance property comprises a first row cycle time (tRC);
the second performance property comprises a second row cycle time (tRC); and
the first row cycle time is shorter than the second row cycle time (tRC).

4. The apparatus of claim 1, wherein:
the memory cells of the first portion have a first cost property;
the memory cells of the second portion have a second cost property; and
the first cost property is higher than the second cost property.

5. The apparatus of claim 1, wherein:
the first portion of memory cells comprises multiple first memory cells, each first memory cell of the multiple first memory cells comprising multiple transistors; and
the second portion of memory cells comprises multiple second memory cells, each second memory cell of the multiple second memory cells comprising exactly one transistor.

6. The apparatus of claim 5, wherein:
each first memory cell of the multiple first memory cells comprises exactly two transistors.

7. The apparatus of claim 5, wherein:
each first memory cell of the multiple first memory cells comprises multiple capacitors; and
each second memory cell of the multiple second memory cells comprises exactly one capacitor.

8. The apparatus of claim 1, wherein:
the first portion of memory cells comprises multiple first memory cells, a first memory cell of the multiple first memory cells coupled to a corresponding first sense amplifier via a first bitline;
the second portion of memory cells comprises multiple second memory cells, a second memory cell of the multiple second memory cells coupled to a corresponding second sense amplifier via a second bitline; and
a first length of the first bitline is shorter than a second length of the second bitline.

9. The apparatus of claim 8, wherein:
the multiple first memory cells are coupled to one or more corresponding first sense amplifiers via multiple first bitlines;
the multiple second memory cells are coupled to one or more corresponding second sense amplifiers via multiple second bitlines; and
a first average length of the multiple first bitlines is less than fifty percent (50%) of a second average length of the multiple second bitlines.

10. The apparatus of claim 1, wherein:
the DRAM array comprises multiple memory banks;
at least one memory bank of the multiple memory banks comprises memory cells of the first portion but lacks memory cells of the second portion; and
at least one other memory bank of the multiple memory banks comprises memory cells of the second portion but lacks memory cells of the first portion.

11. The apparatus of claim 1, wherein:
the DRAM array comprises multiple memory banks; and
at least one memory bank of the multiple memory banks comprises memory cells of the first portion and memory cells of the second portion.

12. The apparatus of claim 11, wherein:
all memory banks of the DRAM array comprise memory cells of the first portion and memory cells of the second portion.

13. The apparatus of claim 1, wherein:
each memory cell of the memory cells of the first portion comprises at least one transistor and at least one capacitor; and
each memory cell of the memory cells of the second portion comprises at least one transistor and at least one capacitor.

14. The apparatus of claim 1, wherein:
the normal data comprises user data.

15. The apparatus of claim 1, wherein the DRAM array comprises:
a third portion of memory cells configured to store usage-based disturbance data.

16. An apparatus comprising:
a memory die comprising a dynamic random-access memory (DRAM) array, the DRAM array comprising:
a first portion of first memory cells configured to store normal data, each first memory cell comprising multiple transistors; and
a second portion of second memory cells configured to store normal data, each second memory cell comprising exactly one transistor.

17. The apparatus of claim 16, wherein the DRAM array comprises:
a third portion of third memory cells configured to store usage-based disturbance data, each third memory cell comprising multiple transistors.

18. The apparatus of claim 17, wherein the DRAM array comprises:
multiple rows, each row of the multiple rows comprising:
third memory cells of the third portion; and
first memory cells of the first portion or second memory cells of the second portion.

19. A method for a memory die, the method comprising:
accessing normal data stored in a first portion of first memory cells of a dynamic random-access memory (DRAM) array, the first memory cells having a first performance property; and
accessing normal data stored in a second portion of second memory cells of the DRAM array, the second memory cells having a second performance property, the first performance property higher than the second performance property.

20. The method of claim 19, further comprising:
accessing usage-based-disturbance data stored in a third portion of third memory cells of the DRAM array, the third memory cells having a third performance property, the first performance property substantially the same as the third performance property.
